(19) United States
(12) Patent Application Publication
(10) Pub. No.: US 2002/0180025 A1
(43) Pub. Date: Dec. 5, 2002

(54) Semiconductor device and method of stacking semiconductor chips

(76) Inventors: Koji Miyata, Yao-shi (JP); Yasuki Fukui, Sakai-shi (JP)

Correspondence Address: NIXON & VANDERHYE P.C., 8th Floor, 1100 North Glebe Road, Arlington, VA, 22201-4714, US

(21) Appl. No.: 10/156,821

(22) Filed: May 30, 2002

(30) Foreign Application Priority Data
May 30, 2001 (JP) 2001-163395

(51) Int. Cl. H01L 21/44; H01L 21/48; H01L 21/50; H01L 23/48; H01L 23/52

(52) U.S. Cl. 257/690; 438/107

(57) ABSTRACT

In a semiconductor device, two or more semiconductor chips are stacked, a first semiconductor chip has electrical contact pads at such positions that form a mirror image of electrical contact pads provided on a second semiconductor chip; and the electrical contact pads on the first semiconductor chip are positioned opposite to and connected to the corresponding electrical contact pads on the second semiconductor chip. Thus, semiconductor chips can be stacked stably. The semiconductor device is reduced in thickness, and a method of stacking semiconductor chips is offered.

### FIELD OF THE INVENTION

The present invention relates generally to a semiconductor device and particularly to such a semiconductor device that multiple semiconductor chips are stacked in a single package and also to a method of stacking semiconductor chips.

### BACKGROUND OF THE INVENTION

Recent mobile phones and other mobile terminals have a capability to download information, such as email and games, over a network, and accordingly require additional functions and capacity in, for example, installed memory. Typically, multiple semiconductor chips are stacked in a single package to achieve larger memory capacity.

Various methods are available to stack semiconductor chips. A popular example is wire bonding whereby semiconductor chips to be stacked are electrically connected to a substrate by means of wires. In the manufacture of packages using wire bonding technology, attention should be paid to avoid damaging wire bonding already formed between the substrate and the semiconductor chip(s) stacked thereon.

In such circumstances, stacking a smaller semiconductor chip on a larger semiconductor chip which is already stacked does not damage the wire bonding formed between the latter and the substrate, since the former is smaller and therefore does not overlap those wire bonding. By contrast, stacking a semiconductor chip on another semiconductor chip of the same type or shape (external dimensions) which is already stacked may damage the wire bonding formed between the latter and the substrate, since the former possibly overlaps those wire bonding.

Some semiconductor devices are suggested to solve these problems: U.S. Pat. No. 5,291,061 dated May 1, 1994 discloses a semiconductor device with an about 200-micron (0.008-inch) spacer sealed between the semiconductor chips to be stacked. Japanese Unexamined Patent Application 6-244360/1994 (Tokukaihei 6-244360) published on Sep. 2, 1994 discloses a semiconductor device with a stepped part formed on semiconductor chips which are relatively thin at their edges and thick at their centers; wire bonding is formed in the stepped part. Japanese Unexamined Patent Application 10-27880/1998 (Tokuhaihei 10-27880) published on Jan. 27, 1998 discloses a semiconductor device with a adhesion layer between the semiconductor chips to be stacked. Another example is a semiconductor device in which a first semiconductor chip is connected “face down” to a substrate and a second semiconductor chip is stacked “face up.”

These semiconductor devices have various problems.

First, in the one disclosed in U.S. Pat. No. 5,291,061, the sealed spacer 54 needs be sufficiently thick, as shown in FIG. 8, so that the bonding wires (wires) 53 that are connected to a first semiconductor chip 51 do not touch a second semiconductor chip 52.

If the bonding wires 53 connected to electrical contact pads 56 on the first semiconductor chip 51 are so high above the electrical contact pads 56 as the spacer 54 is thick, isolation becomes less than desirable between the bonding wires 53 and the second semiconductor chip 52. Thus, the spacer 54 must be sufficiently thick. Spacers thinner than 200-micron or so do not meet this requirement and present an obstacle in trimming down the package (semiconductor device) in thickness.

In the semiconductor device, the spacer 54 cannot be provided where wire bonding exists. Thus, the second semiconductor chip 52 must be horizontally larger than the spacer 54, or of such dimensions that it overhangs the spacer 54, to get bonded by means of wires. Consequently, the second semiconductor chip 52 is easy to vibrate. This leaves us no other choice but to employ forward wire bonding technology in wire bonding the second semiconductor chip 52. In forward wire bonding, wires are coupled first to the semiconductor chip and then to the substrate. The process is termed reverse wire bonding if carried out in the reverse order, that is, wires are coupled first to the substrate and then to the semiconductor chip.

Typically, forward wire bonding causes wires to form a large curve near the contacts to the semiconductor chip; the bonding wires 53 extend too high above the first semiconductor chip 51 and thus from the electrical contact pads 56. This presents difficulty in reducing the semiconductor chip stack and resultant packaging in their thickness.

To reduce the height of the wires in forward wire bonding, “wire bonding terminals” where wires are coupled to the substrate should be relatively close to edges when compared to reverse wire bonding. This presents difficulty in reducing the package (semiconductor device) in horizontal dimensions.

Now, referring to Japanese Unexamined Patent Application 6-244360/1994 according to which the semiconductor device is wire bonded to a stepped part formed on the semiconductor chips which are relatively thin at their edges and thick at their centers (see FIG. 9), the semiconductor chip on which another semiconductor chip is stacked needs have a special shape and therefore requires an additional step of cutting the edges of the semiconductor chip, when compared to conventional cases. To manufacture such a semiconductor chip with its edges thinned down, the semiconductor chip needs be cut off the wafer on its back, i.e., the face where no devices are provided, so as to protect the other face where devices are mounted. Accordingly, a separate step has to be provided to turn over either the semiconductor wafer or semiconductor chips using a specially designed device. Manufacturing costs increase for these reasons.

The stepped part, formed along the edges of the second semiconductor chip 52, is not electrically isolated for structural reasons of the chip. If the semiconductor chip is thinned down across the chip or the step is made smaller for reduced thickness in the resultant package, the bonding wires 53 are not sufficiently isolated from the second semiconductor chip 52. The stepped part loses its mechanical strength, and the second semiconductor chip 52 may possibly develop cracks or otherwise break.

Wire bonding must be formed on the stepped part using no other techniques but forward wire bonding as in the case of the semiconductor device having a sealed spacer between the stacked semiconductor chips. It is therefore difficult to stack semiconductor chips and form a package with reduced thickness and horizontal dimensions for the same reasons as with the spacer-sealed semiconductor device.

Next, referring to Japanese Unexamined Patent Application 10-27880 disclosing a semiconductor device having an adhesion layer between stacked semiconductor chips (see FIG. 10), the bumps 57 must be sufficiently isolated from the second semiconductor chip 52, and it is difficult to design the adhesion layer 55 with suitable thickness and area. This is not the only problem: The substrate may be polluted by, for example, intrusion of voids or bleeding of achieves material. The second semiconductor chip 52 may tilt after being stacked.

Stacking two or more semiconductor chips exaggerates various problems, including substrate pollution and excessive chip height and tilt, and makes it difficult to manufacture chips stably and free of these problems. Thinning down the adhesion layer 55, and hence the package will undesirable result in insufficient isolation between the bonding wires 53 and the second semiconductor chip 52.

Further referring to the semiconductor device provided with the adhesion layer 55 between the stacked first and second semiconductor chips 51, 52, the semiconductor chips 51, 52 must be bonded by means of wires using no other techniques but forward wire bonding as in the case of semiconductor device having a sealed spacer between the stacked semiconductor chips. It is therefore difficult to stack semiconductor chips and form a package with reduced thickness and horizontal dimensions for the same reasons as with the spacer-sealed semiconductor device.

Referring to the next example, i.e., the semiconductor device with the first semiconductor chip connected face down to a substrate and the second semiconductor chip stacked face down on the substrate (see FIG. 11), a bumps 57 must be formed of gold or solder on each electrical contact pads 56 on the first semiconductor chip 51 before the first semiconductor chip 51 is connected to the substrate 58: specifically, when the wafer is yet to be cut (diced) into the first semiconductor chips 51 or it is already diced but the resultant chips are yet to be fabricated. These requirements increase the manufacturing cost.

In none of the foregoing conventional semiconductor devices, the wires cannot be lowered upon the stacking of semiconductor chips, sealing resin (not shown) used to seal the semiconductor chips may undesirable flow along the wires.

### SUMMARY OF THE INVENTION

The present invention has objectives to offer a thinned-down semiconductor device and a method of stably stacking semiconductor chips.

To achieve the aforementioned objectives, a semiconductor device of the present invention includes multiple semiconductor chips which are stacked, wherein:

a first semiconductor chip has electrical contact pads at such positions that form a mirror image of electrical contact pads on a second semiconductor chip; and

the electrical contact pads on the first semiconductor chip are positioned opposite to and connected to the associated electrical contact pads on the second semiconductor chip.

To achieve the aforementioned objectives, a semiconductor device of the present invention includes multiple semiconductor chips which are stacked, wherein:

electrical contact pads on a first semiconductor chip are positioned opposite to and connected to electrical contact pads on a second semiconductor chip; and

an identical signal is supplied to electrical contact pads which are interconnected.

Here, by saying that the electrical contact pads on the first semiconductor chip are positioned opposite to the associated electrical contact pads on the second semiconductor chip, we mean that the surface of the first semiconductor chip on which components are formed is positioned opposite to the surface of the second semiconductor chip on which components are formed and also that electrical contact pads are provided on those surfaces. Further, by saying that the electrical contact pads on one chip are at such positions that form a mirror image of those on the other, we mean that the electrical contact pads to which a common signal is supplied are positioned opposite to each other when the first semiconductor chip is positioned opposite to the second semiconductor chip. That is, the interconnected electrical contact pads receive the same signal. Specifically, for example, when the first semiconductor chip and the second semiconductor chip are of the same type and dimensions, the second electrical contact pads on the second semiconductor chip are linearly symmetrical to the first electrical contact pads on the first semiconductor chip (with respect to any side of the surface of the first semiconductor chip on which components are formed).

With the arrangement, when the first semiconductor chip and the second semiconductor chip are positioned opposite to each other, the electrical contact pads on the semiconductor chips are interconnected, and a common signal is supplied via the interconnected electrical contact pads to the first semiconductor chip and the second semiconductor chip. In other words, those electrical contact pads to which an identical signal is fed are interconnected. Thus, the first semiconductor chip and the second semiconductor chip can be simultaneously driven with a single signal input. The two semiconductor chips can hence share common wiring using the electrical contact pads, which makes it possible to offer semiconductor devices which are thinner than conventional semiconductor chips each of which has its own wiring.

With the arrangement, the first semiconductor chip is positioned opposite to and electrically connected to the second semiconductor chip. As a result, those electrical contact pads that are oppositely positioned are interconnected, and there is no need to consider the insulation between the first semiconductor chip and the second semiconductor chip. Therefore, unlike conventional cases, there is no need to provide a spacer or adhesion layer to ensure insulation between the first semiconductor chip and the second semiconductor chip, which makes it possible to offer thinner semiconductor devices.

To achieve the aforementioned objectives, a method of stacking multiple semiconductor chips of the present invention includes the steps of:

placing electrical contact pads on a first semiconductor chip and electrical contact pads on a second semiconductor chip at opposite positions, the second semiconductor chip having the electrical contact pads at such positions that form a mirror image of the electrical contact pads on the first semiconductor chip; and

connecting the electrical contact pads on the first semiconductor chip to the corresponding electrical contact pads on the second semiconductor chip.

With the arrangement, the electrical contact pads on the first semiconductor chip are placed at such positions that form a mirror image of the electrical contact pads on the second semiconductor chip. That is, a common signal is supplied to interconnected electrical contact pads. Thus, the first semiconductor chip and the second semiconductor chip can share wiring connecting them to the substrate, and therefore requires fewer wires.

With the arrangement, the first semiconductor chip is connected to the second semiconductor chip. That is, the electrical contact pads positioned opposite each other are interconnected, and there is no need to consider insulation between the first semiconductor chip and the second semiconductor chip. Therefore, unlike conventional cases, there is no need to provide a spacer or adhesion layer to ensure insulation between the first semiconductor chip and the second semiconductor chip, which makes it possible to offer thinner semiconductor devices.

For a fuller understanding of the nature and advantages of the invention, reference should be made to the ensuing detailed description taken in conjunction with the accompanying drawings.

### BRIEF DESCRIPTION OF THE DRAWINGS

FIG. 1, depicting a major part of a semiconductor device of an embodiment of the present invention, is a cross-sectional view schematically showing the structure of a semiconductor device in which semiconductor chips are stacked.

FIG. 2 is a cross-sectional view showing the structure of a semiconductor device of an embodiment of the present invention.

FIG. 3(a) is an explanatory drawing sequentially illustrating the manufacture of the semiconductor device of FIG. 2.

FIG. 3(b) is an explanatory drawing sequentially illustrating the manufacture of the semiconductor device of FIG. 2.

FIG. 3(c) is an explanatory drawing sequentially illustrating the manufacture of the semiconductor device of FIG. 2.

FIG. 3(d) is an explanatory drawing sequentially illustrating the manufacture of the semiconductor device of FIG. 2.

FIG. 3(e) is an explanatory drawing sequentially illustrating the manufacture of the semiconductor device of FIG. 2.

FIG. 3(f) is an explanatory drawing sequentially illustrating the manufacture of the semiconductor device of FIG. 2.

FIG. 3(g) is an explanatory drawing sequentially illustrating the manufacture of the semiconductor device of FIG. 2.

FIG. 3(h) is an explanatory drawing sequentially illustrating the manufacture of the semiconductor device of FIG. 2.

FIG. 4 is a cross-sectional view showing the structure of a major part of a semiconductor device of another embodiment of the present invention.

FIG. 5 is a cross-sectional view showing the structure of a major part of a semiconductor device of another embodiment of the present invention.

FIG. 6 is a cross-sectional view showing the structure of a major part of a semiconductor device of another embodiment of the present invention.

FIG. 7 is a cross-sectional view showing the structure of a major part of a semiconductor device of another embodiment of the present invention.

FIG. 8 is a cross-sectional view illustrating a conventional semiconductor device in which a spacer is sealed between stacked semiconductor chips.

FIG. 9 is a cross-sectional view illustrating a conventional semiconductor device in which a semiconductor chip is thinned down at its edges compared to its center.

FIG. 10 is a cross-sectional view illustrating a conventional semiconductor device in which an adhesion layer is interposed between semiconductor chips.

FIG. 11 is a cross-sectional view illustrating a conventional semiconductor device in which a first semiconductor chip is connected face down to a substrate and a second semiconductor chip is stacked face up.

### DESCRIPTION OF THE EMBODIMENTS

### EMBODIMENTS 1

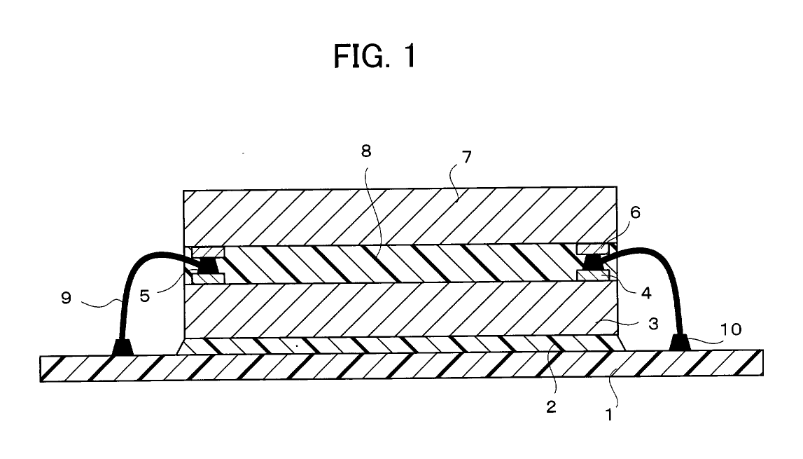

The following will describe an embodiment of the present invention in reference to FIGS. 1-3.

The semiconductor device of the present embodiment is a semiconductor device in which two or more semiconductor chips are stacked. Electrical contact pads are provided to both a first semiconductor chip and a second semiconductor chip at such positions that they form a mirror image on the first and second semiconductor chips, so those on the first semiconductor chip are located opposite to those on the second semiconductor chip when the first and second semiconductor chips are placed opposite to each other.

The method of stacking semiconductor chip of the present embodiment includes the steps of: placing the first and second semiconductor chips so that they are opposite to each other, the first and second semiconductor chips having electrical contact pads at such positions that they form a mirror image on the first and second semiconductor chips; and coupling the electrical contact pads on the first semiconductor chip to the associated electrical contact pads on the second semiconductor chip.

Although the description below will focus on structures in which the electrical contact pads on the semiconductor chips are coupled to a substrate by wire bonding, connections may be formed between the electrical contact pads and the substrate using different methods.

The semiconductor device of the present embodiment includes, for example, two semiconductor chips, one stacked on the other. Referring to FIG. 1, the semiconductor device includes a substrate 1, an adhesion layer 2, a first chip (first semiconductor chip) 3, first pads (electrical contact pads) 4, bumps (wire bumps) 5, second pads (electrical contact pads) 6, a second chip (second semiconductor chip) 7, an interlayer adhesion layer 8, wires 9, and wire bonding terminals 10. The first and second semiconductor chips (chips) will be referred collectively to as “chips” when there is no need to distinguish between them. Likewise, the two kinds of electrical contact pads (pads) will be referred collectively to as “pads” where appropriate.

The substrate 1 has the first chip 3 and the second chip 7 stacked thereon, interposed by the adhesion layer 2. The substrate 1 is not limited in any particular manner and may be any given substrate: examples include leadframes with wire bonding terminals 10 and organic substrates made of polyimide resin, BT resins (bismaleimide triazine resins), and the like. The substrate 1 has patterned wiring (not shown) formed thereon.

The adhesion layer 2 may be formed from an adhesive agent in the form of liquid or sheet. There are however no particular restrictions on the material or type of the adhesive agent provided that the agent can be uniformly applied across the surface of the first chip 3 where the chip 3 is adhered to the substrate 1, i.e., the surface with no components formed thereon, for adhesion to the substrate 1.

The first pads 4 are formed on the surface of the first chip 3 where components are provided. The second pads 6 are formed on the surface of the second chip 7 where components are provided. The first chip 3 and the second chip 7 may be of the same type or of different types: there are no restrictions. The positions of the first pads 4 and the second pads 6 will be detailed later.

The interlayer adhesion layer 8 may be formed from an adhesive agent in the form of liquid or sheet: examples include, and are not limited to, liquid epoxy adhesive agents and liquid adhesive agents having anisotropic conductivity. The interlayer adhesion layer 8 may be formed from the same adhesive agent as or different adhesive agents from the adhesion layer 2.

The bumps 5 are formed using wire bonding when the substrate is connected to the first chip 3 and the second chip 7. The bumps 5 may not be formed in some cases if a method other than wire bonding is employed to connect the first pads 4 and the second pads 6 to the substrate 1. The bumps 5 may be suitably formed from gold or solder, but not limited to these materials.

Typically, a chip has many terminals or pads on its surface for electric signal (signal) inputs and outputs.

The first pads 4 and the second pads 6 are therefore provided in large numbers on the first chip 3 and the second chip 7 respectively. Various signals, both incoming and outgoing, are transmitted via these first and second pads 4, 6.

Irrespective of whether the first chip 3 and the second chip 7 are of the same type or of different types, the first chip 3 and the second chip 7 have input terminals for common signals. An example is a power supply terminal.

In the semiconductor device of the present embodiment, the first pads 4 and the second pads 6 are connected with each other via the bumps 5. An identical signal is coupled to the first and second pads 4, 6 connected to a common bump 5. The first and second pads 4, 6 via which an identical signal is transmitted are provided at such positions that they form a mirror image on the first and second chips 3, 7. Here, the term, “mirror image,” should not be interpreted narrowly as referring to physically symmetrical positions, but broadly encompasses such positions that the first and second pads 4, 6 coupled together at a common bump 5 can receive the same signal when the two chips are placed opposite to each other. A concrete example on the assumption that the first chip 3 and the second chip 7 are of the same type and dimensions is the first pads 4 on the first chip 3 and the second pads 6 on the second chip 7 that are linearly symmetrical (with respect to any side of the surface of the first chip 3 on which components are formed).

Hence, the associated first pad 4 and second pad 6 receive an identical signal via a part where the two pads are connected. The configuration makes it possible for the associated first pad 4 and second pad 6 to share a common wire 9 which connects those first and second pads 4, 6 to the substrate 1. The configuration reduces the thickness of the resultant semiconductor device in comparison with conventional configurations in which each chip has wires of its own.

If the first and second chips 3, 7 are of the same type, the signals transmitted via the first and second pads 4, 6 are of the same type of similar types and come in the same number or in similar numbers. For these reasons, the first chip 3 and the second chip 7 are preferably of the same type for a greater number of pads and bumps sharing common wires.

If the first and second chips 3, 7 are of different types, the first pad 4 and the second pad 6 via which an identical signal is fed, are sufficiently provided at such positions that they form a mirror image.

Depending on the type and exterior of the chip and the number of pads, for example, a signal which is effective only with the first pad 4 (first chip 3) may be fed to the part where the first pad 4 is connected to a second pad 6, in which events the signal should be fed only to the chip (first chip 3) which is operative with the signal, and not to the other chip (second chip 7). To this end, isolate the circuitry on the chip from the pad to which unnecessary signal is fed. This is achieved, for example, by replacing any pad where unnecessary signal is fed with a dummy pad (selective contact) which is isolated from the on-chip circuitry. Alternatively, substitute a chip-enabling pad which is a pad connected to a circuit (selective contact) which selects among incoming signals. Other solutions are also available.

Specifically, for example, if the first chip 3 and the second chip 7 receive different numbers of signals, the chip receiving less signals have some pads isolated from the on-chip circuitry. Other solutions are also available, but not explicitly described here. The aforementioned selective contact is only required to be capable of selecting among incoming signals to the first chip 3 and the second chip 7. The method of providing a selective contact is limited in no particular manner: examples include the formation of a dummy pad and the provision of a circuit which distinguishes among incoming signals.

The method of separately driving the first chip 3 and the second chip 7 is limited in no particular manner: concrete examples include: providing the first chip 3 with a selective contact or a circuit designed to operate only with a high active signal input and the second chip 7 with a selective contact or a circuit designed to operate only with a low active signal input; and providing pads (selective contacts) via which only either of the chips can receive the signal for selectively driving the relevant one of the chips when a signal is coupled to the pad. Other solutions are also available. When the first chip 3 and the second chip 7 are separately driven, the first chip 3 and the second chip 7 may be of the same type or of different types.

The first chip 3 and the second chip 7 may be memory chips. Less signals are fed to a memory chip than other types of semiconductor chips. It is therefore easy to manufacture a memory chip and its mirror-image chip. This allows for an increased number of common wires 9 when the first chip 3 and the second chip 7 are memory chips. The description here applies likewise when either one of the first chip 3 and the second chip 7 is a memory chip.

In the semiconductor device of the present embodiment, the substrate 1 is connected to the first pads 4 and the second pads 6 using reverse wire bonding. Wire bonding is principally classified into forward wire bonding and reverse wire bonding. Forward wire bonding is a technique to first connect wires to a semiconductor chip, followed by connecting the wires to a substrate. If the sequence is reversed, i.e., the wires are connected to the substrate first, before being connected to the chip, the technique is called reverse wire bonding.

Reverse wire bonding provides wires that rise relatively low above the on-chip pads when compared to forward wire bonding. Employing reverse wire bonding therefore allows for further reducing the thickness of the semiconductor device.

Nevertheless, in the semiconductor device of the present invention, the substrate may be connected to the pads using methods other than forward wire bonding and reverse wire bonding.

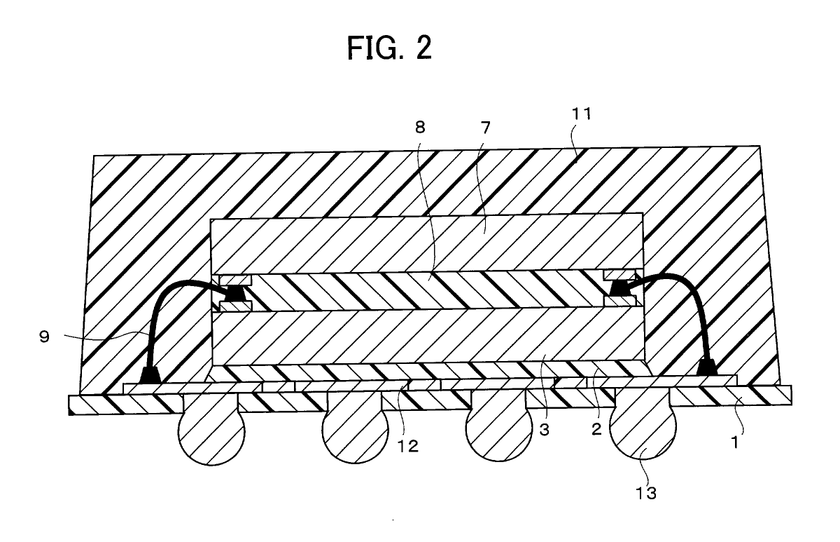

The semiconductor device of the present embodiment has been so far described assuming that the first chip 3 and the second chip 7 are stacked on the substrate 1; this is however not the only available possibility, any given number of chips may be stacked. After stacking any number of chips, sealing 11 is formed from a sealing agent to provide protection to the chips from surrounding environments and external stress. FIG. 2 shows a semiconductor device package including chips. The sealing agent may be a thermosetting resin: especially preferred examples include epoxy and silicon resins. On the back of the substrate 1 (the surface on which no chips are mounted) are there provided external terminals (external contact terminals) 13 which provides the substrate 1 with electric contacts to the outside of the semiconductor device.

The semiconductor device of the present embodiment is arranged so that the first chip 3 and the second chip 7 are stacked on the substrate 1. The bumps 5 are formed between the first pads 4 on the first chip 3 and the second pads 6 on the second chip 7. The sealing 11 is formed by, for example, applying a sealing agent to the surface of the second chip 7 on which no components are formed. No bumps 5 exist on the surface of the second chip 7 which is coated with a sealing agent. Therefore, unlike conventional cases, the height of the bumps, formed on the surface to be coated with a sealing agent, does not require special attention in the formation of the sealing 11. This allows for use of the sealing agent in a smaller amount.

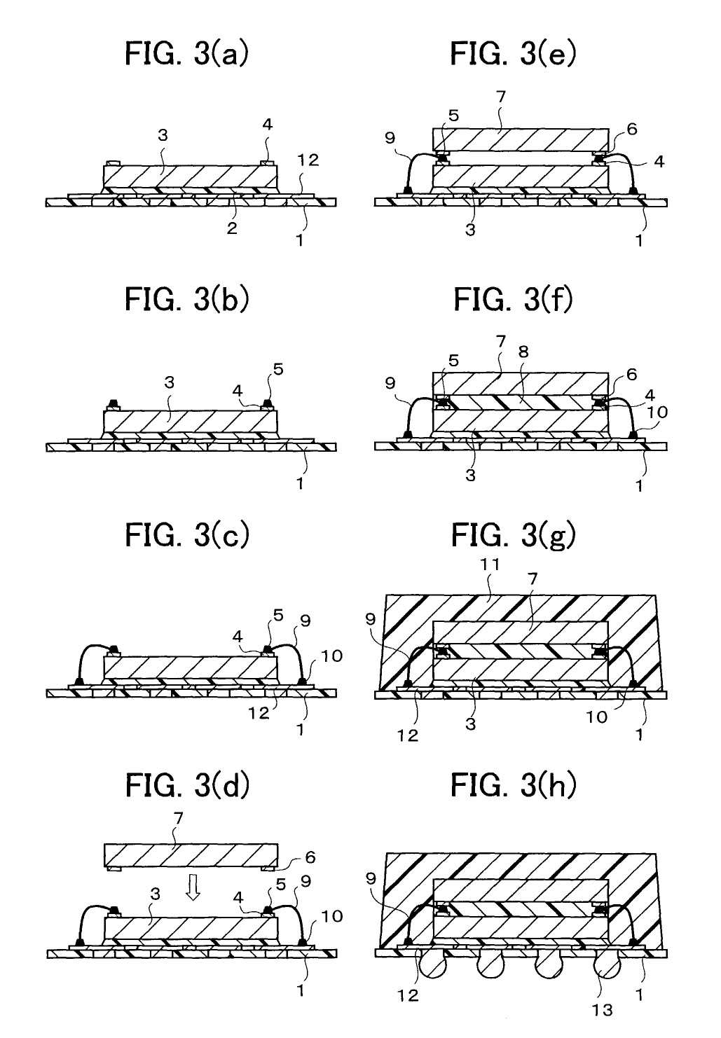

The method of manufacturing a semiconductor device having the foregoing arrangement will be described by way of, and not limited to, an example, in reference to FIGS. 3(a)-3(h), assuming that the first semiconductor chip and the second semiconductor chip are of the same type and also that the substrate is connected to the electrical contact pads by means of reverse wire bonding.

As shown in FIG. 3(a), to form the adhesion layer 2, an adhesive agent is first applied across the surface of the first chip 3 on which no components are formed (on the back of the surface on which components are formed). Thereafter, the surface of the first chip 3 on which no components are formed is pasted to the surface of the substrate 1 on which patterned wiring 12 is already provided (step 1) , at which time the first pads 4 are already formed on the surface of the first chip 3 on which components are formed. The adhesion layer 2 may have any thickness, but is preferably somewhere between 15 micron and 30 micron to obtain a package with reduced thickness.

Now, as shown in FIG. 3(b) , the bumps 5 are formed on the first pads 4 on the first chip 3 (step 2). There are no particular restrictions on the height of the bumps 5, but 40 micron to 60 micron will be preferred to obtain a package with reduced thickness.

Next, as shown in FIG. 3(c) , wires 9 are formed connecting the wire bonding terminals 10 on the patterned wiring 12 to the bumps 5 on the first pads 4 using reverse wire bonding (step 3).

Next, as shown in FIG. 3(d), the second chip 7 with the second pads 6 is stacked on the bumps 5 on the first pads 4 on the first chip 3 (step 4) so that the first pads 4 on the first chip 3 form a mirror image of the second pads 6 on the second chip 7, that is, an identical signal is fed to the part where a first pad 4 and an associated second pad 6 are connected. In addition, chip-enabling pads (not shown) enabling selection between the chips are placed at “different positions” in the stacking of the first chip 3 and the second chip 7. Different positions refer to those positions where the chip-enabling pads on one chip are not electrically connected to the chip-enabling pad on the other. After the step, the first chip 3 and the second chip 7 are placed so that their surfaces on which components are formed face each other.

Next; as shown in FIG. 3(e) , adjustment is made to position the first pads 4 on the first chip 3 directly over the corresponding second pads 6 on the second chip 7. Applying pressure and heat to the second chip 7 now establishes the connection between the first pads 4 and the second pads 6 via bumps 5 (step 5) . The pressure applied to the second chip 7 is appropriately 500 g to 2000 g per chip and the heat is appropriately about 100° C. to 300° C.

Next, as shown in FIG. 3(f), an interlayer adhesion layer 8 is formed from an adhesive agent between the first chip 3 and the second chip 7 (step 6). The adhesive agent is not limited in any particular manner. Preferably used is a liquid epoxy adhesive agent. The method of forming the interlayer adhesion layer 8 is not limited to the foregoing method. For example, the interlayer adhesion layer 8 may be formed by applying an anisotropically conductive, liquid adhesive agent or sheet-like adhesive agent onto the second chip 7 after step 3, that is, before the second pads 6 are stacked on the bumps 5, and then carrying out step 4, in which event, step 5 is carried out to concurrently set the adhesive agent and connect the first pads 4 to the second pads 6 by means of the application of pressure and heat to the second chip 7.

Next, as shown in FIG. 3(g), the sealing 11 is formed from a sealing agent to protect the patterned wiring 12 and the like including the first chip 3, the second chip 7, the wires 9, and the wire bonding terminals 10 from surrounding environments, external stress, and other undesirable conditions (step 7), using transfer mold or injection mold or by means of application or printing of a liquid resin. Other sealing methods are also available.

Next, as shown in FIG. 3(h) , external terminals 13 are formed to provide electrodes extending external to the semiconductor device from the patterned wiring 12 connected via the wires 9 to the pads 4, 6 on the first chip 3 and the second chip 7 (step 8). The external terminals 13 are electrically connected to the patterned wiring 12 via the substrate 1. The external terminals 13 are made of solder in many cases, but may be made of other materials.

Carrying out steps 1-8 in this order concludes the manufacture of a semiconductor device in which those pads to which an identical signal is transmitted are connected to each other. Steps 1-6 are repeated as necessary if two or more chips are to be stacked, so the semiconductor device can be manufactured with any number of stacked chips. The repetition of the process is applicable to other embodiments too.

The wires 9 are connected using (reverse) wire bonding in step 3. The bumps 5 are formed and wire bonding is used here, because wire bonding, both forward and reverse, does not require new equipment, for example, and thus saves cost in comparison to other bonding techniques.

Forward wire bonding delivers wires about 130 micron to 160 micron high (as measured above the pads), whereas reverse wire bonding delivers wires about 40 micron to 60 micron high. Accordingly, the employment of reverse wire bonding, in comparison to forward wire bonding, further reduces the thickness of the resultant package.

In the aforementioned example of the manufacture method, the wires 9 are connected using reverse (wire) bonding. This is not the only method available. Other bonding methods may be used.

As described in the foregoing, the semiconductor device of the present embodiment is arranged so that: the surface of the first chip 3 on which components are formed is placed facing the surface of the second chip 7 on which components are formed; and identical signals are supplied to the first pads 4 and the second pads 6 which are connected to each other via the same bumps 5.

With the arrangement, the first chip 3 and the second chip 7 can be driven simultaneously with a single signal input, and the pads on the two chips share common wiring. The resultant semiconductor device is thinner than in conventional cases where each chip has its own wiring.

In the semiconductor device of the present embodiment, the substrate 1 is preferably connected to the first pads 4 and the second pads 6 using reverse wire bonding.

With the arrangement, wire bonding does not require new equipment and thus saves on manufacturing costs in comparison to other bonding techniques. The employment of reverse wire bonding, in comparison to forward wire bonding, further reduces the thickness of the resultant semiconductor device.

### EMBODIMENTS 2

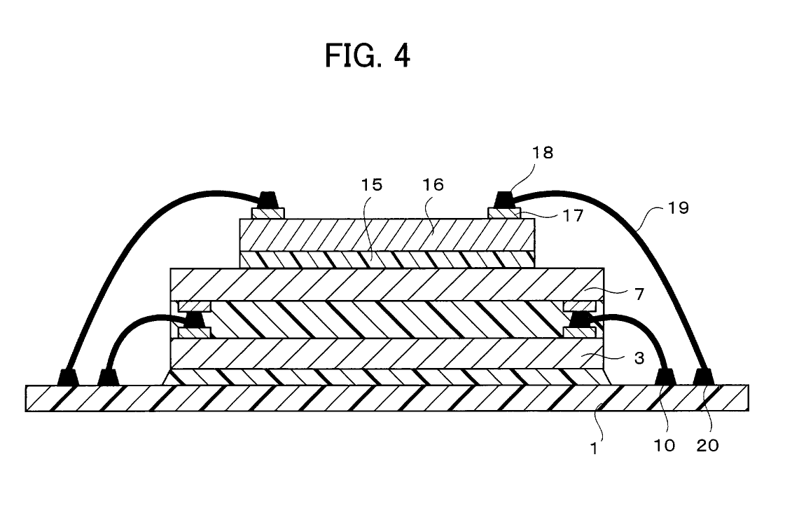

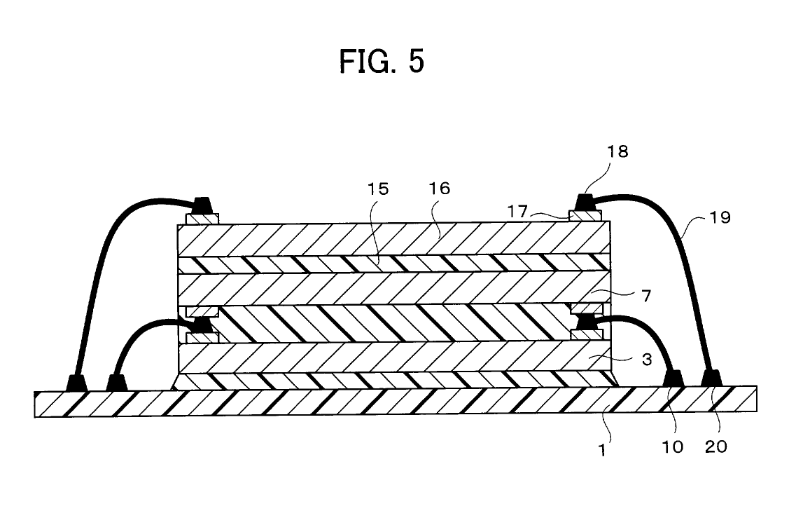

Referring to FIGS. 4, 5, the following will describe another embodiment of the present invention. Here, for convenience, members of the present embodiment that have the same arrangement and function as members (arrangement) shown in figures of embodiment 1, and that are mentioned in that embodiment are indicated by the same reference numerals and description thereof is omitted.

In the semiconductor device of the present embodiment, as shown in FIGS. 4, 5, a third chip (third semiconductor chip) 16 is stacked on a second chip 7 with an adhesion layer 15 interposed between them and has thereon third pads 17 which are electrically connected to the substrate 1. The third chip 16 has third pads (electrical contact pads) 17 on which are there formed bumps 18. The third pads 17 are connected by wires 19 to wire bonding terminals 20 on patterned wiring (not shown) on the substrate 1.

The third chip 16 may be of the same type as or of a different type from the first chip 3 and the second chip 7, and is not limited in any particular manner. The third chip 16 may be of the same exterior (dimensions) as or smaller than the first chip 3 and the second chip 7.

The adhesion layer 15 may be formed from the same adhesive agent as or a different adhesive agent from the interlayer adhesion layer 8, and is not limited in any particular manner.

The wire bonding terminals 20 may be formed at the same positions as the wire bonding terminals 10 (the wire bonding terminals 10 may be used) or at different positions from the wire bonding terminals 10, if the third chip 16 is of the same type as the first chip 3 and the second chip 7. If the wire bonding terminals 20 are formed at different positions from the wire bonding terminals 10, the wire bonding terminals 20 are formed outside the wire bonding terminals 10 (further distanced from the chip). The semiconductor device of the present embodiment is otherwise arranged in the same manner as (includes other members that are common to) that of embodiment 1.

The semiconductor device is manufactured by means of steps 1-6, followed by applying an adhesive agent from which the adhesion layer 15 is formed across the whole back surface of the third chip 16 to the surface on which components are formed (the surface on which no components are formed) so as to paste and stack the third chip 16 to the back of the second chip 7. Here, the third chip 16 is provided with the third pads 17 on the surface on which components are formed. The adhesion layer 15 is not limited in any particular manner in terms of thickness, provided that the second chip 7 is completely isolated from the third chip 16. About 15 micron to 30 micron is preferable to obtain a package with reduced thickness.

Next, the bumps 18 are formed on the third pads 17 and connected to the wire bonding terminals 20 on the substrate 1 using forward wire bonding or reverse wire bonding. At this stage, no bumps are formed between the third chip 16 and the second chip 7; therefore, the adhesion layer 15 is sufficiently thick if it ensures isolation.

As described in the foregoing, the semiconductor device of the present embodiment is arranged so that: the second chip (second semiconductor chip) 7 is stacked on the substrate 1, and the third chip (third semiconductor chip) 16 is further stacked thereon with the intervening adhesion layer 15; and the third pads (electrical contact pads) 17 on the third chip 16 are electrically connected to the substrate 1.

Thus, another semiconductor chip can be stacked, the manufactured semiconductor device has a reduced thickness.

### EMBODIMENTS 3

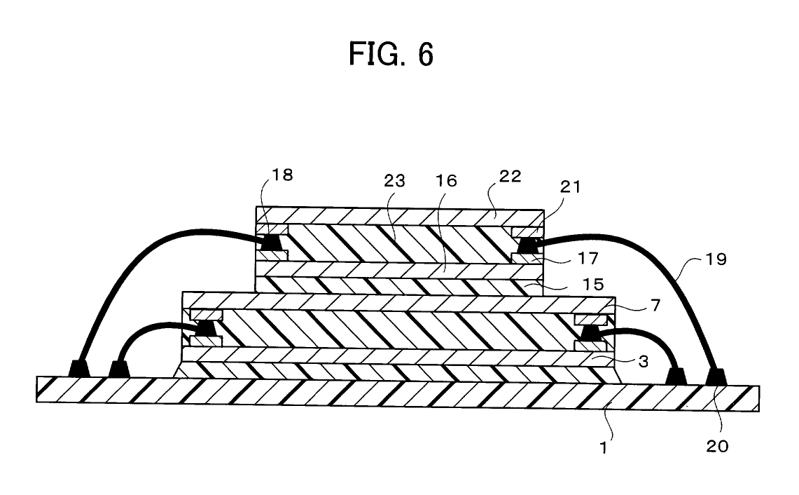

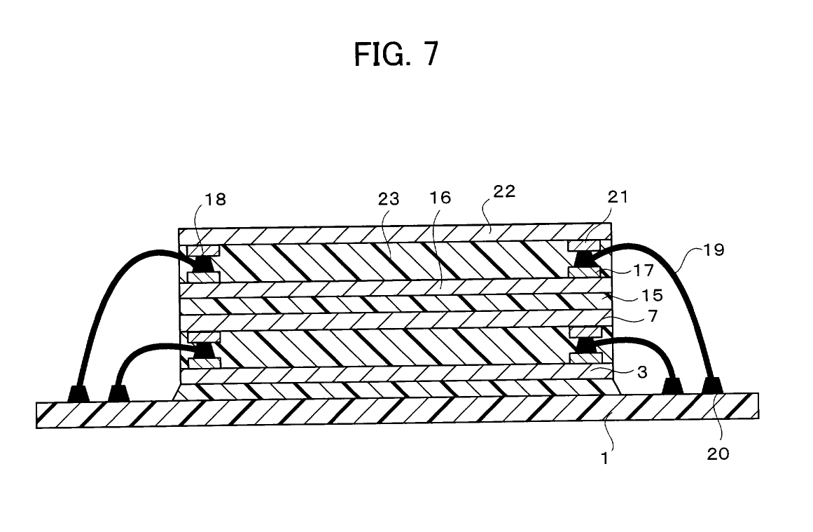

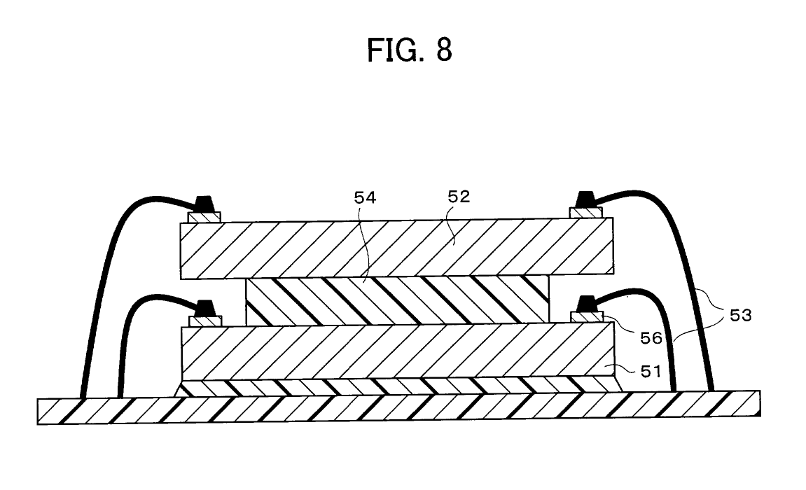

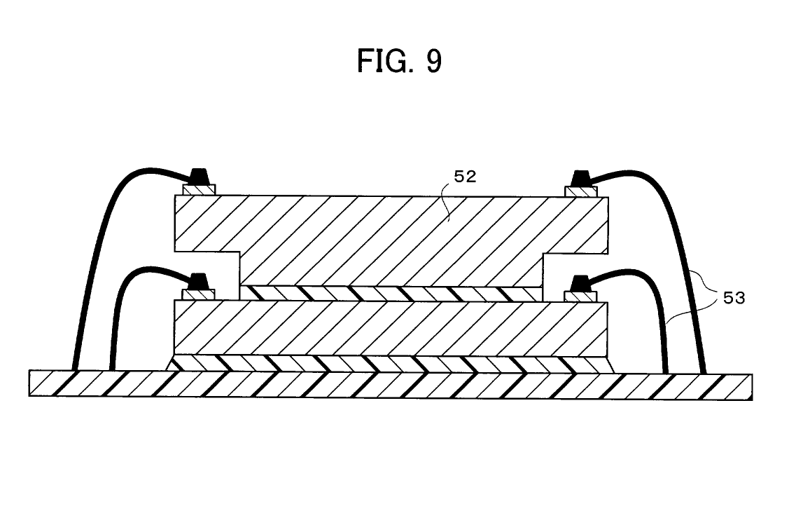

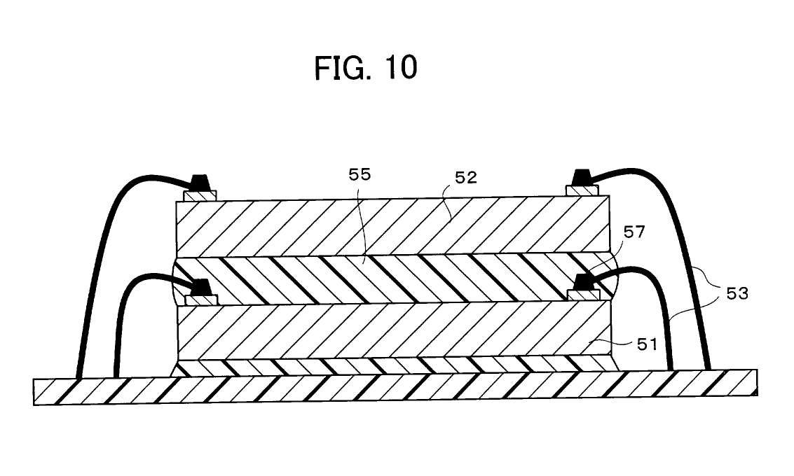

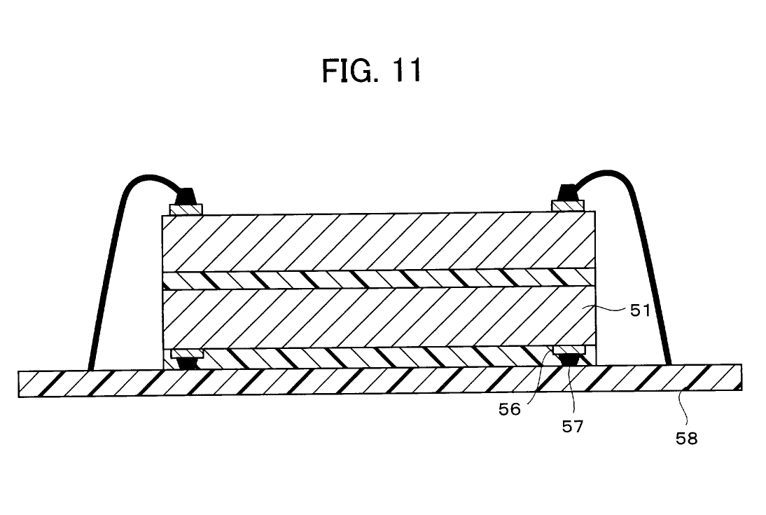

Referring to FIGS. 6, 7, the following will describe another embodiment of the present invention. Here, for convenience, members of the present embodiment that have the same arrangement and function as members (arrangement) shown in figures of embodiments 1, 2 and that are mentioned in that embodiment are indicated by the same reference numerals and description thereof is omitted.

In the semiconductor device of the present embodiment, as shown in FIG. 6 and FIG. 7, a fourth chip (fourth semiconductor chip) 22 is stacked on a third chip 16 like mirror images. The third pads 17 on the third chip 16 form a mirror image of and connected to fourth pads 21 on the fourth chip 22 via bumps 18. Hence, an identical signal is supplied to the third pad 17 and the fourth pad 21 connected thereto. An interlayer adhesion layer 23 is formed between the third chip 16 and the fourth chip 22. The semiconductor device of the present embodiment is otherwise arranged in the same manner as (includes other members that are common to) those of embodiments 1, 2.

The fourth chip 22 may be of the same type or of a different type from the first chip 3, the second chip 7, and the third chip 16, and is not limited in any particular manner. However, the fourth chip 22 is connected to the third chip 16 and therefore preferably is of the same dimensions (exterior) and type as the third chip 16. The third chip 16 and the fourth chip 22 may be memory chips.

The interlayer adhesion layer 23 may be formed from an any adhesive agent, but preferably formed from the same adhesive agent as the interlayer adhesion layer 8.

The semiconductor device is manufactured in the same manner as in embodiment 2 up to the point where the bumps 18 are connected to the wire bonding terminals 20 by the wires 19, followed by stacking the fourth pads 21 on the fourth chip 22 onto the bumps 18. Here, the fourth chip 22 is stacked on the third chip 16 so that the third pads 17 form a mirror image of the fourth pads 21. In the stacking of the fourth chip 22 on the third chip 16, chip-enabling pad (not shown) enabling selection between the chips are placed at different positions. The chip-enabling pad may be stacked at the same positions if the first chip 3 and the second chip 7 are provided with circuitry that distinguishes between high active and low active signals.

Next, adjustment is made to position the third pads 17 on the third chip 16 directly over the corresponding fourth pads 21 on the fourth chip 22. Applying pressure and heat to the fourth chip 22 now establishes the connection between the third pads 17 and the fourth pads 21 via the bumps 18. The pressure and the heat applied to the fourth chip 22 is more or less the same as to those applied to the second chip 7.

As described in the foregoing, the semiconductor device of the present embodiment further includes the fourth chip (fourth semiconductor chip) 22 and is arranged so that: the fourth pads (electrical contact pads) 21 are provided on the fourth chip 22 at positions opposite to those of the third pads (electrical contact pads) 17 on the third chip (third semiconductor chip) 16; the third chip 16 is provided with the third pads 17 at positions that form an mirror image of the fourth pads 21 on the fourth chip 22; and the third pads 17 on the third chip 16 are placed opposite to the fourth pads 21 on the fourth chip 22.

Thus, the manufactured semiconductor device includes more semiconductor chips has a reduced thickness.

As described in the foregoing, a semiconductor device of the present invention includes multiple semiconductor chips which are stacked and is arranged so that:

a first semiconductor chip has electrical contact pads at such positions that form a mirror image of electrical contact pads on a second semiconductor chip; and

the electrical contact pads on the first semiconductor chip are positioned opposite to and connected to the associated electrical contact pads on the second semiconductor chip.

Another semiconductor device of the present invention includes multiple semiconductor chips which are stacked and is arranged so that:

electrical contact pads on a first semiconductor chip are positioned opposite to and connected to electrical contact pads on a second semiconductor chip; and

an identical signal is supplied to electrical contact pads which are interconnected.

Here, by saying that the electrical contact pads on the first semiconductor chip are positioned opposite to the associated electrical contact pads on the second semiconductor chip, we mean that the surface of the first semiconductor chip on which components are formed is positioned opposite to the surface of the second semiconductor chip on which components are formed and also that electrical contact pads are provided on those surfaces. Further, by saying that the electrical contact pads on one chip are at such positions that form a mirror image of those on the other, we mean that the electrical contact pads to which a common signal is supplied are positioned opposite to each other when the first semiconductor chip is positioned opposite to the second semiconductor chip. That is, the interconnected electrical contact pads receive the same signal. Specifically, for example, when the first semiconductor chip and the second semiconductor chip are of the same type and dimensions, the second electrical contact pads on the second semiconductor chip are linearly symmetrical to the first electrical contact pads on the first semiconductor chip (with respect to any side of the surface of the first semiconductor chip on which components are formed).

With the arrangement, when the first semiconductor chip and the second semiconductor chip are positioned opposite to each other, the electrical contact pads on the semiconductor chips are interconnected, and a common signal is supplied via the interconnected electrical contact pads to the first semiconductor chip and the second semiconductor chip. In other words, those electrical contact pads to which an identical signal is fed are interconnected. Thus, the first semiconductor chip and the second semiconductor chip can be simultaneously driven with a single signal input. The two semiconductor chips can hence share common wiring using the electrical contact pads, which makes it possible to offer semiconductor devices which are thinner than conventional semiconductor chips each of which has its own wiring.

With the arrangement, the first semiconductor chip is positioned opposite to and electrically connected to the second semiconductor chip. As a result, those electrical contact pads that are oppositely positioned are interconnected, and there is no need to consider the insulation between the first semiconductor chip and the second semiconductor chip. Therefore, unlike conventional cases, there is no need to provide a spacer or adhesion layer to ensure insulation between the first semiconductor chip and the second semiconductor chip, which makes it possible to offer thinner semiconductor devices.

Preferably, the semiconductor device of the present invention is further arranged so that the electrical contact pads on the first semiconductor chip and the second semiconductor chip are connected to a substrate by bonding wires.

The method of connecting by bonding wires does not require any special devices, but relies on conventional devices to connect the electrical contact pads to the substrate.

Preferably, the semiconductor device of the present invention is further arranged so that the first semiconductor chip and the second semiconductor chip are of the same type of semiconductor chip.

With the arrangement, semiconductor chips of the same type receive the same number of input signals and can, in stacking the semiconductor chips, be provided with more contacts where identical signals are supplied (those parts where the electrical contact pads on the first semiconductor chip and the second semiconductor chip are interconnected) . Further, using the same type of semiconductor chips makes it easy in manufacturing semiconductor chips to manufacture a semiconductor chip with electrical contact pads positioned so as to form a mirror image of those on the other semiconductor chip. That is, semiconductor chips are easily manufactured with electrical contact pads to which identical signals are supplied at such positions to form a mirror image, when the semiconductor chips positioned opposite to each other.

The inclusion of the same type of semiconductor chips makes it possible to offer semiconductor devices with increased driving capacity compared to the inclusion of different types of semiconductor chips.

By stacking semiconductor chips which are required (essential) for the driving of the device, the two semiconductor chips work as a backup to each other when one of them breaks down. Therefore, the inclusion of the same type of semiconductor chips makes it possible to offer reliable semiconductor devices.

Preferably, the semiconductor device of the present invention is further arranged so that the semiconductor chips of the same type are memory chips.

Less signals are fed to a memory chip than other types of semiconductor chips. It is therefore easy to design the mirror image. This allows for easy manufacture of the aforementioned semiconductor devices and reduction to practice of the present invention.

By mounting many a memory chip efficiently, semiconductor devices can be offered with more memory capacity.

Preferably, the semiconductor device of the present invention is further arranged so that the first semiconductor chip and the second semiconductor chip are provided with selective contacts each of which switches between operation states according to an input signal.

Preferably, the semiconductor device of the present invention is further arranged so that one of the associated electrical contact pads on the first semiconductor chip and the second semiconductor chip connected to each other is a dummy pad.

With the arrangement, the first semiconductor chip and the second semiconductor chip are each provided with selective contacts. When a signal is fed to the selective contact or a particular signal is fed to the selective contact, the semiconductor chip provided with the selective contact can operate (driven or stands by). In other words, the semiconductor chips can each operate separately without interference from the other semiconductor chip.

By substituting a dummy pad for one of the electrical contact pads of the interconnected first and second semiconductor chips, it becomes possible to easily operate the semiconductor chips separately.

As described in the foregoing, a method of stacking semiconductor chips of the present invention includes the steps of:

placing electrical contact pads on a first semiconductor chip and electrical contact pads on a second semiconductor chip at opposite positions, the second semiconductor chip having the electrical contact pads at such positions that form a mirror image of the electrical contact pads on the first semiconductor chip; and

connecting the electrical contact pads on the first semiconductor chip to the corresponding electrical contact pads on the second semiconductor chip.

With the arrangement, the electrical contact pads on the first semiconductor chip are placed at such positions that form a mirror image of the electrical contact pads on the second semiconductor chip. That is, a common signal is supplied to interconnected electrical contact pads. Thus, the first semiconductor chip and the second semiconductor chip can share wiring connecting them to the substrate, and therefore requires fewer wires.

With the arrangement, the first semiconductor chip is connected to the second semiconductor chip. That is, the electrical contact pads positioned opposite to each other are interconnected, and there is no need to consider insulation between the first semiconductor chip and the second semiconductor chip. Therefore, unlike conventional cases, there is no need to provide a spacer or adhesion layer to ensure insulation between the first semiconductor chip and the second semiconductor chip, which makes it possible to stack thinner semiconductor chips.

Preferably, the method of stacking semiconductor chips of the present invention is further arranged so that the connecting step is done using reverse wire bonding.

The process whereby wires are coupled to the substrate first before coupled to the semiconductor chips is termed reverse wire bonding, which is the reverse of forward wire bonding.

Reverse wire bonding allows for lower wire heights above the electrical contact pads on the semiconductor chips than forward wire bonding and also for positioning of wire bonding terminals closer to the semiconductor chips than forward wire bonding, which makes it possible to offer thinner and smaller semiconductor devices.

With the arrangement, no bumps are formed on the outside surface of the outside surface of the semiconductor chip (surface which contacts a sealing agent) in wire bonding. Therefore, in forming sealing from a sealing agent, unlike conventional cases, there is no need to consider the height of the bumps formed on the surface which contacts the sealing agent, the sealing agent is used in a smaller amount. Thus, stacking semiconductor chips is easy and thinner semiconductor devices can be offered.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor device, comprising multiple semiconductor chips which are stacked,
wherein:
a first semiconductor chip has electrical contact pads at such positions that form a mirror image of electrical contact pads on a second semiconductor chip; and
the electrical contact pads on the first semiconductor chip are positioned opposite to and connected to the associated electrical contact pads on the second semiconductor chip.

2. The semiconductor device as defined in claim 1, wherein
the electrical contact pads on the first semiconductor chip and the second semiconductor chip are connected to a substrate by bonding wires.

3. The semiconductor device as defined in claim 1, wherein
the first semiconductor chip and the second semiconductor chip are of the same type of semiconductor chip.

4. The semiconductor device as defined in claim 3, wherein
the first semiconductor chip and the second semiconductor chip are memory chips.

5. The semiconductor device as defined in claim 1, wherein
the first semiconductor chip and the second semiconductor chip are provided with selective contacts each of which switches between operation states according to an input signal.

6. The semiconductor device as defined in claim 5, wherein
the selective contact is a circuit which selects among input signals.

7. The semiconductor device as defined in claim 1, wherein
one of the associated electrical contact pads on the first semiconductor chip and the second semiconductor chip connected to each other is a dummy pad.

8. The semiconductor device as defined in claim 1, further comprising a third semiconductor chip stacked on the second semiconductor chip via an adhesion layer,
wherein
the third semiconductor chip is provided with electrical contact pads which are electrically connected to a substrate.

9. The semiconductor device as defined in claim 1, further comprising a fourth semiconductor chip,
wherein:
the fourth semiconductor chip has electrical contact pads at such positions that form a mirror image of the electrical contact pads on the third semiconductor chip; and
the electrical contact pads on the fourth semiconductor chip are positioned opposite to and connected to the associated electrical contact pads on the third semiconductor chip.

10. A semiconductor device, comprising multiple semiconductor chips which are stacked,
wherein:
electrical contact pads on a first semiconductor chip are positioned opposite to and connected to electrical contact pads on a second semiconductor chip; and
an identical signal is supplied to electrical contact pads which are interconnected.

11. The semiconductor device as defined in claim 10, wherein
the electrical contact pads on the first semiconductor chip and the second semiconductor chip are connected to a substrate by bonding wires.

12. The semiconductor device as defined in claim 10, wherein
the first semiconductor chip and the second semiconductor chip are of the same type of semiconductor chip.

13. The semiconductor device as defined in claim 12, wherein
the first semiconductor chip and the second semiconductor chip are memory chips.

14. The semiconductor device as defined in claim 10, wherein
the first semiconductor chip and the second semiconductor chip are provided with selective contacts each of which switches between operation states according to an input signal.

15. The semiconductor device as defined in claim 14, wherein
the selective contact is a circuit which selects among input signals.

16. The semiconductor device as defined in claim 10, wherein
one of the associated electrical contact pads on the first semiconductor chip and the second semiconductor chip connected to each other is a dummy pad.

17. The semiconductor device as defined in claim 10, further comprising a third semiconductor chip stacked on the second semiconductor chip via an adhesion layer,
wherein
the third semiconductor chip is provided with electrical contact pads which are electrically connected to a substrate.

18. The semiconductor device as defined in claim 10, further comprising a fourth semiconductor chip,
wherein:
the fourth semiconductor chip has electrical contact pads which are positioned opposite to and connected to the electrical contact pads on the third semiconductor chip; and
an identical signal is supplied to electrical contact pads which are interconnected.

19. A method of stacking semiconductor chips, comprising the steps of:
placing electrical contact pads on a first semiconductor chip and electrical contact pads on a second semiconductor chip at opposite positions, the second semiconductor chip having the electrical contact pads at such positions that form a mirror image of the electrical contact pads on the first semiconductor chip; and
connecting the electrical contact pads on the first semiconductor chip to the corresponding electrical contact pads on the second semiconductor chip.

20. The method of stacking semiconductor chips as defined in claim 19, wherein
the connecting step is done using reverse wire bonding.

21. The method of stacking semiconductor chips as defined in claim 19, wherein
the first semiconductor chip and the second semiconductor chip are of the same type of semiconductor chip.

22. The method of stacking semiconductor chips as defined in claim 19, wherein
the first semiconductor chip and the second semiconductor chip are provided with selective contacts each of which switches between operation states according to an input signal.

23. The method of stacking semiconductor chips as defined in claim 19, wherein
one of the associated electrical contact pads on the first semiconductor chip and the second semiconductor chip connected to each other is a dummy pad.
